(19) United States
(12) Patent Application Publication
(10) Pub. No.: US 2026/0107804 A1
(43) Pub. Date: Apr. 16, 2026

(54) SEMICONDUCTOR PACKAGE

(71) Applicant: Samsung Electronics Co., Ltd., Suwon-si (KR)

(72) Inventor: Hongjin Kim, Suwon-si (KR)

(21) Appl. No.: 19/293,285

(22) Filed: Aug. 7, 2025

(30) Foreign Application Priority Data
Oct. 10, 2024 (KR) 10-2024-0137867

(51) Int. Cl. H01L 23/498; H01L 23/00; H01L 25/18; H10B 80/00; H10D 80/30

(52) U.S. Cl. CPC H10W 70/65; H10W 90/701; H10B 80/00; H10D 80/30; H10W 74/15; H10W 90/00; H10W 90/724; H10W 90/734

(57) ABSTRACT

A semiconductor package includes a substrate including a plurality of insulating layers and a plurality of interconnection layers stacked in a first direction, and a semiconductor chip including a plurality of first pads and mounted on the substrate. The plurality of interconnection layers include an uppermost interconnection layer, including a plurality of second pads. The plurality of second pads include a second signal pad electrically connected to a first signal pad. With respect to a top down view, an area defined by the outermost boundary of the first signal pad is fully included in an overlapping region formed therebelow in the substrate. Throughout the overlapping region between the second signal pad and the lowermost interconnection layer, each pair of two adjacent insulating layers contact each other.

### CROSS-REFERENCE TO RELATED APPLICATION(S)

This application claims benefit of priority to Korean Patent Application No. 10-2024-0137867 filed on Oct. 10, 2024 in the Korean Intellectual Property Office, the disclosure of which is incorporated herein by reference in its entirety.

### BACKGROUND

The present inventive concept relates to a semiconductor package.

A semiconductor package may include a substrate and a semiconductor chip, and the semiconductor chip may be mounted on the substrate through various types of bumps. The semiconductor chip may receive power from the substrate through the bumps. Alternatively, the semiconductor chip may transmit a signal to the substrate or receive a signal from the substrate through the bumps. Recently, as high performance and high capacitance of a semiconductor package mounted on an electronic device are required, a semiconductor chip based on the universal flash storage (UFS) standard may be used. As the data transmission speed of signals transmitted and received by semiconductor chips is gradually increasing, research is being conducted to improve the quality of the signal transmission.

### SUMMARY

An aspect of the present inventive concept is to provide a semiconductor package having improved quality of a signal transmission by reducing parasitic capacitance of a substrate to minimize a change in characteristic impedance.

According to an aspect of the present inventive concept, a semiconductor package includes a substrate including a plurality of insulating layers and a plurality of interconnection layers stacked in a first direction, a semiconductor chip including a plurality of first pads, and mounted on the substrate, and a plurality of chip bumps disposed between the plurality of first pads and the substrate. The plurality of interconnection layers include an uppermost interconnection layer and a lowermost interconnection layer, each interconnection layer of the plurality of interconnection layers is disposed in a corresponding insulating layer among the plurality of interconnection layers, the uppermost interconnection layer includes a plurality of second pads that are electrically connected to the plurality of first pads through the plurality of chip bumps, the plurality of second pads are in contact with one of the plurality of insulating layers, the plurality of first pads include a first signal pad, and the plurality of second pads include a second signal pad that is electrically connected to the first signal pad. With respect to a top down view, an area defined by an outermost boundary of the first signal pad is fully included in an overlapping region disposed therebelow in the substrate. Throughout the overlapping region between the second signal pad and the lowermost interconnection layer, each pair of two adjacent insulating layers among the plurality of insulating layers contact each other.

According to an aspect of the present inventive concept, a semiconductor package includes a substrate including a plurality of insulating layers and a plurality of interconnection layers, a semiconductor chip mounted on the substrate, and a plurality of chip bumps disposed between the substrate and the semiconductor chip. The plurality of interconnection layers include an uppermost interconnection layer disposed at an uppermost portion of the substrate and a lowermost interconnection layer disposed in a lowermost portion of the substrate, and the uppermost interconnection layer includes a first signal pad. With respect to a top down view, an area defined by an outermost boundary of the first signal pad is fully included in a first region formed therebelow in the substrate. Within the first region in the substrate, no electrically conductive layers are disposed between the first signal pad and the lowermost interconnection layer.

According to an aspect of the present inventive concept, a semiconductor package includes a substrate including a plurality of insulating layers and a plurality of interconnection layers; a semiconductor chip including a plurality of first pads and mounted on the substrate in a first direction; a plurality of chip bumps disposed on an upper surface of the substrate; and a plurality of package bumps disposed on a lower surface of the substrate, wherein the plurality of interconnection layers include a plurality of second pads connected to the plurality of first pads and the plurality of chip bumps, and a plurality of third pads connected to the plurality of package bumps, and only the plurality of insulating layers are disposed in an overlapping region of the substrate excluding the plurality of third pads, in a region of the substrate overlapping at least one second signal pad in the first direction, among the plurality of second pads.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view simply illustrating a semiconductor package according to an embodiment.

FIG. 2 is a cross-sectional view illustrating a semiconductor package according to an embodiment.

FIG. 3 is a plan view illustrating region ‘A’ of a semiconductor package according to the embodiment illustrated in FIG. 2.

FIG. 4 is an enlarged cross-sectional view illustrating region ‘A’ of a semiconductor package according to the embodiment illustrated in FIG. 2.

FIG. 5 is a view simply illustrating a plurality of interconnection layers to illustrate an overlapping region according to an embodiment.

FIG. 6 is a cross-sectional view illustrating a semiconductor package according to an embodiment.

FIG. 7 is an enlarged cross-sectional view illustrating region ‘A’ of a semiconductor package according to the embodiment illustrated in FIG. 6.

FIG. 8 is a view simply illustrating a plurality of interconnection layers to illustrate an overlapping region according to an embodiment.

FIG. 9 is a view illustrating a semiconductor package according to an embodiment.

FIG. 10 is a cross-sectional view illustrating a semiconductor package according to an embodiment.

FIG. 11 is a perspective view illustrating a semiconductor package according to an embodiment.

FIG. 12 is a side view illustrating a semiconductor package according to the embodiment illustrated in FIG. 11.

### DETAILED DESCRIPTION

Hereinafter, preferred embodiments will be described with reference to the attached drawings as follows.

Terms such as “constant,” “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

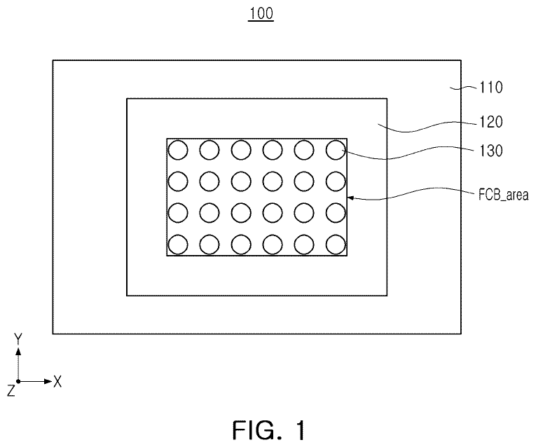

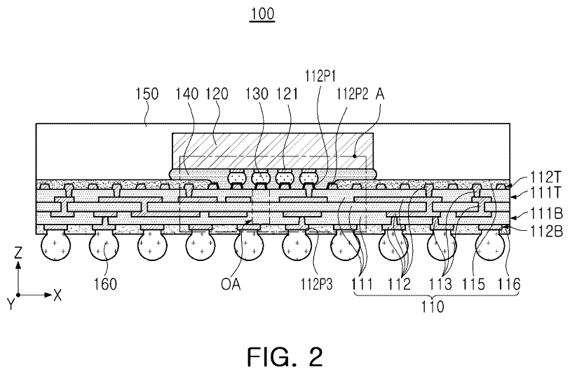

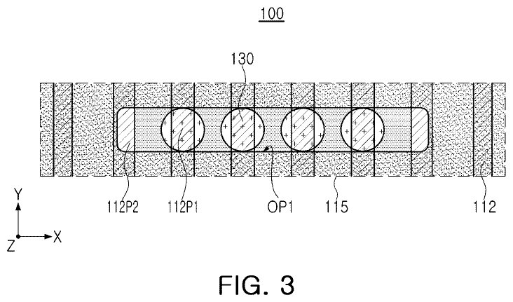

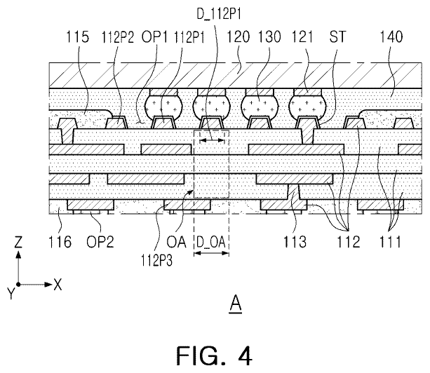

FIG. 1 is a plan view simply illustrating a semiconductor package according to an embodiment. FIG. 2 is a cross-sectional view illustrating a semiconductor package according to an embodiment. FIG. 3 is a plan view illustrating region ‘A’ of a semiconductor package according to the embodiment illustrated in FIG. 2. FIG. 4 is an enlarged cross-sectional view illustrating region ‘A’ of a semiconductor package according to the embodiment illustrated in FIG. 2.

Referring to FIGS. 1 to 4, a semiconductor package 100 according to an embodiment may include a substrate 110, a semiconductor chip 120, and a plurality of chip bumps 130.

The substrate 110 may be a support substrate on which the semiconductor chip 120 is mounted, and may be a package substrate for wiring a plurality of first pads (chip pads) 121 of the semiconductor chip 120. For example, the substrate 110 may electrically connect the plurality of first pads to an external circuit. The package substrate may include a printed circuit board (PCB), a ceramic substrate, a glass substrate, a tape wiring substrate, or the like. For example, the substrate 110 may be an interposer substrate, for example, an organic interposer. As another example, the substrate 110 may be a module substrate, and, in this case, the semiconductor chip 120 may be a semiconductor structure, such as a semiconductor package.

The substrate 110 may include a plurality of insulating layers 111, a plurality of interconnection layers 112, a plurality of interconnection vias 113, a first solder mask layer 115, and a second solder mask layer 116. The plurality of insulating layers 111 and the plurality of interconnection layers 112 may be alternately stacked in a first direction (Z-axis of FIGS. 1 to 3). For example, the plurality of insulating layers 111 and the plurality of interconnection layers 112 may be alternately stacked along an axis extending parallel to the first direction. Also, as can be seen, the plurality of interconnection layers 112 and the plurality of interconnection vias 113 may be formed in the plurality of insulating layers 111, respectively. For example, each interconnection layer of the plurality of interconnection layers 112 may be formed in a corresponding insulating layer of the plurality of insulating layers 111.

In some embodiments, the substrate 110 may include a plurality of insulating layers 111, a plurality of interconnection layers 112, and a plurality of interconnection vias 113. In addition, a semiconductor package may include a first solder mask layer 115 and a second solder mask layer 116, which are disposed on an upper and lower surfaces of the substrate 110.

As shown in an embodiment illustrated in FIG. 2, the substrate 110 may include three insulating layers 111 and four interconnection layers 112. The number of the plurality of insulating layers 111 and the number of the plurality of interconnection layers 112 are not limited thereto.

The plurality of insulating layers 111 may include an insulating material, and may include a thermosetting resin such as an epoxy resin or a thermoplastic resin such as a polyimide. For example, the plurality of insulating layers 111 may include a photosensitive insulating material such as a photoimagable dielectric (PID) resin. Alternatively, the plurality of insulating layers 111 may include a resin mixed with an inorganic filler, for example, an Ajinomoto build-up film (ABF). Alternatively, the plurality of insulating layers 111 may include a prepreg, a FR-4 (flame retardant), or a bismaleimide triazine (BT). Each of the plurality of insulating layers 111 may include the same or different materials. The plurality of insulating layers 111 may not have a distinct boundary therebetween, depending on materials thereof, processes for forming thereof, or the like.

Each of the plurality of interconnection layers 112 may include interconnection patterns, for example, an interconnection line or a redistribution line. Each of the plurality of interconnection layers 112, the interconnection vias 113, and combination thereof may form all or part of an electrical path. By the plurality of interconnection layers 112 and the interconnection vias 113, the semiconductor chip 120 may electrically communicate with an external region of the semiconductor chip 120, e.g., a fan-out region not overlapping the semiconductor chip 120 in the first direction. Therefore, the semiconductor package 100 of the present embodiment may be referred to as a fan-out semiconductor package. A shape of the semiconductor package is not limited thereto, and in some embodiments, the semiconductor package 100 may form a fan-in semiconductor package.

The plurality of interconnection layers 112 may include interconnection patterns such as a ground pattern, a power pattern, and a signal pattern. The interconnection vias 113 may be used to connect two interconnection patterns. The ground pattern may be used to provide a ground voltage (e.g. VSS) as an electrical reference during the operation of the semiconductor chip 120, and may be connected to circuit elements that operate when receiving a ground voltage. The power pattern may be used to provide a power voltage (e.g., VDD) to provide power required for the operation of the semiconductor chip 120, and may be connected to circuit elements that operate when receiving a power voltage. Each of the ground voltage and the power voltage may have a constant magnitude of frequency and/or a constant magnitude of voltage, such that the respective circuit elements are configured to receive such constant magnitude of frequency or voltage for operation.

The signal pattern may be a path (or a part of a path) through which the semiconductor chip 120 exchanges data with an external device or an external semiconductor chip. The signal pattern may be a path through which not only data but also a control signal may be transmitted and/or exchanged. For example, the control signal may include a command signal, a clock signal, or the like, and may be a signal of which a magnitude of frequency and/or a magnitude of signal are not constant.

The plurality of interconnection layers 112 may be disposed in a linear shape on an XY plane (two-dimensional flat surface in a three-dimensional coordinate system). The plurality of interconnection layers 112 may be patterned into interconnection patterns. The interconnection vias 113 may have a cylindrical shape, a side surface of which is inclined such that a width of the interconnection vias 113 decreases in either a downward or upward direction. The interconnection vias 113 are illustrated as a filled via structure in which an internal space is completely filled with a conductive material, but they are not limited thereto. For example, the interconnection vias 113 may have a conformal via shape in which a metal material is formed along an inner wall of a via hole, without completely filling the internal space.

The plurality of interconnection layers 112 and the interconnection vias 113 may include a conductive material, for example, copper (Cu), aluminum (Al), silver (Ag), tin (Sn), gold (Au), nickel (Ni), lead (Pb), titanium (Ti), or an alloy thereof. Depending on a width of an interconnection or an interval between interconnections in the plurality of interconnection layers 112, the interconnection of the plurality of interconnection layers 112 may be implemented as a redistribution line.

The plurality of interconnection layers 112 may include a plurality of second pads 112P1, a plurality of fourth pads 112P2, and a plurality of third pads 112P3, exposed through the first and second solder mask layers 115 and 116. Some of uppermost interconnection layers 112T disposed in an uppermost portion, among the plurality of interconnection layers 112, may form a plurality of second and fourth pads 112P1 and 112P2. Some of lowermost interconnection layers 112B disposed in a lowermost portion, among the plurality of interconnection layers 112, may form a plurality of third pads 112P3.

The plurality of second and fourth pads 112P1 and 112P2 may be disposed on an uppermost insulating layer 111T disposed in an uppermost portion, among the plurality of insulating layers 111, and the plurality of third pads (lower pads) 112P3 may be disposed on a lowermost insulating layer 111B disposed in a lowermost portion, among the plurality of insulating layers 111. The plurality of second pads (upper pads) 112P1 may be pads for mounting the semiconductor chip 120. The plurality of second pads 112P1 may be pads fully exposed by the first solder mask layer 115 and connected to the plurality of chip bumps 130. Depending on a design, the plurality of fourth pads 112P2 may be omitted (may not be formed). Each of the plurality of second and fourth pads 112P1 and 112P2 may have a cylindrical shape, a side surface of which is inclined such that a diameter of each of the plurality of second and fourth pads 112P1 and 112P2 increases in a downward direction (along a direction toward the substrate).

The plurality of fourth pads 112P2 may be pads that may be at least partially exposed by the first solder mask layer 115, and may not be connected to the plurality of chip bumps 130. In the plurality of fourth pads 112P2, upper surfaces and side surfaces exposed from the first solder mask layer 115 may be covered with a non-conductive film layer 140, and may be in contact with the non-conductive film layer 140.

The first and second solder mask layers 115 and 116 may be solder resist layers protecting the plurality of interconnection layers 112 from external physical and chemical damage. The first and second solder mask layers 115 and 116 may include an insulating material such as a prepreg, an ABF, FR-4, BT, a photo-solder resist (PSR), or the like. The first solder mask layer 115 may include a first opening OP1 exposing the plurality of second and/or fourth pads 112P1 and 112P2. The second solder mask layer 116 may include a plurality of second openings OP2 exposing the plurality of third pads 112P3.

The first solder mask layer 115 may be spaced apart from at least some of the plurality of second and fourth pads 112P1 and 112P2. The first solder mask layer 115 may be spaced apart from the plurality of second pads 112P1. The overlapping region OA may be spaced apart entirely from the first solder mask layer 115.

In some embodiments, the first solder mask layer 115 may include a plurality of first openings OP1 exposing the plurality of second and/or fourth pads 112P1 and 112P2.

Each of the plurality of second and fourth pads 112P1 and 112P2 may include a surface treatment layer ST disposed on a surface exposed from the first solder mask layer 115. In some embodiments, the surface treatment layer ST may be omitted (may not be formed), depending on a design. The surface treatment layer ST may be disposed on an entire surface of the plurality of second pads 112P1 and on an exposed portion of surfaces of the plurality of fourth pads 112P2.

The surface treatment layer ST may include at least one of gold (Au), silver (Ag), nickel (Ni), or palladium (Pd). Unlike as illustrated in FIGS. 2 and 3, the plurality of third pads 112P3 may further include a surface treatment layer ST disposed on a surface exposed from the second solder mask layer 116.

The plurality of third pads 112P3 may be disposed on the lowermost insulating layer 111B, and may be exposed downward through a plurality of upper and lower passages of the second solder mask layer 116, to be electrically connected to a plurality of package bumps 160. Each of the plurality of third pads 112P3 may have upper and lower surfaces having a circular or polygonal shape. As a diameter of each of the plurality of package bumps 160 increases, a width of each of the plurality of third pads 112P3 may also increase.

Referring to FIGS. 2 to 4, the uppermost interconnection layers 112T located in the uppermost portion, among the plurality of interconnection layers 112, may protrude from the uppermost insulating layer 111T located in the uppermost portion, among the plurality of insulating layers 111. The lowermost interconnection layers 112B located in the lowermost portion, among the plurality of interconnection layers 112, may protrude from the lowermost insulating layer 111B located in the lowermost portion, among the plurality of insulating layers 111. For example, the substrate 110 of the embodiment illustrated in FIGS. 2 to 4 may be a protruded trace substrate (PTS).

Unlike those illustrated in FIGS. 2 to 4, the substrate 110 may also be an embedded trace substrate (ETS). The ETS may have a structure recessed in upward and downward directions in a region in which the uppermost insulating layer 111T overlaps the plurality of second and fourth pads 112P1 and 112P2, and the plurality of second and fourth pads 112P1 and 112P2 may be in contact with the uppermost insulating layer 111T in recessed spaces of the uppermost insulating layer 111T.

The semiconductor chip 120 may be disposed to overlap the substrate 110 in the first direction. For example, the semiconductor chip 120 may be mounted on the substrate 110 in the first direction (e.g., along an axis extending parallel to the first direction). The semiconductor chip 120 may include a plurality of first pads 121, and the plurality of first pads 121 may be disposed on a lower surface of the semiconductor chip 120. The semiconductor chip 120 may be mounted on an upper surface of the substrate 110 in a flip-chip bonding manner.

The semiconductor chip 120 may further include a device layer (not illustrated) and a semiconductor substrate (not illustrated). The device layer may include a chip interconnection layer, chip interconnection vias, and a chip insulation layer. The semiconductor substrate may include an element layer and a body portion. The element layer may include an integrated circuit (IC). The semiconductor chip 120 may include a logic semiconductor chip and/or a memory semiconductor chip.

The logic semiconductor chip may be a microprocessor, and may be, for example, a central processing unit (CPU), a graphic processing unit (GPU), a field programmable gate array (FPGA), an application processor (AP), a digital signal processor, an encryption processor, a controller, or an application specific integrated circuit (ASIC). The memory semiconductor chip may be a volatile memory, such as a dynamic random access memory (DRAM), a static random access memory (SRAM), or the like, or a non-volatile memory, such as a flash memory or the like.

The body portion of the semiconductor chip 120 may include silicon (Si), germanium (Ge), gallium arsenide (GaAs), or the like, and the plurality of first pads 121 may include a conductive material, such as tungsten (W), aluminum (Al), copper (Cu), or the like. The plurality of first pads 121 may be pads of a bare chip, for example, aluminum (Al) pads, but may also be pads of a packaged chip, for example, copper (Cu) pads, according to embodiments.

The plurality of first pads 121 may be electrically connected to the plurality of second pads 112P1 through the plurality of chip bumps 130. As used herein, components described as being “electrically connected” are configured such that an electrical signal can be transferred from one component to the other (although such electrical signal may be attenuated in strength as it is transferred and may be selectively transferred). For example, being electrically connected may mean providing at least a portion of a path through which a signal is transmitted.

In some embodiments, the plurality of first pads 121 may be disposed within the body portion of the semiconductor chip 120 such that a lower surface thereof forms a lower surface of the semiconductor chip 120. In some embodiments, a passivation layer exposing the plurality of first pads 121 may be further disposed on the lower surface of the semiconductor chip 120. The passivation layer may include a silicon oxide film and/or a silicon nitride film.

The plurality of chip bumps 130 may be disposed between the plurality of first pads 121 and the substrate 110. The plurality of chip bumps 130 may electrically connect the plurality of interconnection layers 112 and the plurality of first pads 121. Specifically, some of the uppermost interconnection layers 112T may be implemented as a plurality of interconnection pads, and the plurality of interconnection pads may be the plurality of second pads 112P1. The plurality of chip bumps 130 may be connected and fixed between the plurality of second pads 112P1 and each of the plurality of first pads 121.

The plurality of chip bumps 130 may be disposed in a central region (FCB_area) of the lower surface of the semiconductor chip 120, and a size of the central region (FCB_area) may be equal to or smaller than a size of the lower surface of the semiconductor chip 120. The plurality of chip bumps 130 may be disposed along at least one of a second direction (X-axis of FIGS. 1 to 3) or a third direction (Y-axis of FIGS. 1 to 3) of the substrate 110. The plurality of chip bumps 130 may be disposed at (by) regular intervals. Arrangement of the plurality of chip bumps 130 is not limited to the embodiment illustrated in FIG. 1.

The plurality of chip bumps 130 may include a conductive material having a low melting point, such as lead (Pb), bismuth (Bi), tin (Sn), or a tin alloy (Sn—Ag—Cu). At a temperature which is higher than the melting point of the conductive material, the plurality of chip bumps 130 may be brought into a fluid state by a reflow process or a thermal compression bonding (TCB) process. Thereafter, as the temperature decreases, the plurality of chip bumps 130 may be connected and fixed between the plurality of first pads 121 and the plurality of second pads 112P1. Therefore, the semiconductor chip 120 may be mounted on the substrate 110. The chip bumps 130 may have a ball shape, or a pin shape, and may be formed as a single layer or multiple layers. For example, the chip bumps 130 may be solder balls. The chip bumps 130 may have circular, triangular or other polygonal shapes, and may be conductive elements similar to grid elements (e.g., lands), which are used in a land grid array (LGA) package.

The non-conductive film layer 140 may be disposed to surround the plurality of chip bumps 130 between the semiconductor chip 120 and the substrate 110. The non-conductive film layer 140 may also be referred to as an underfill layer. The non-conductive film layer 140 may include a non-conductive polymer, and may include a non-conductive paste (NCP). The non-conductive film layer 140 may be formed on the lower surface of the semiconductor chip 120 or the upper surface of the substrate 110 during the reflow process or the TCB process, and then may fill a space between the semiconductor chip 120 and the substrate 110. Therefore, the non-conductive film layer 140 may have a shape protruding outward from end portions of the semiconductor chip 120. A length of the non-conductive film layer 140 protruding horizontally from side surfaces of the semiconductor chip 120 may be greater in a central portion in a thickness direction, as compared to in the lower surface and the upper surface. For example, the protruding portion of the non-conductive film layer 140 may have a rounded surface.

An encapsulant 150 may seal and protect the semiconductor chip 120. The encapsulant 150 may be disposed to cover the side surfaces and the upper surface of the semiconductor chip 120, but is not limited thereto. The encapsulant 150 may include a molding material such as an epoxy molding compound (EMC), but is not limited thereto. For example, the encapsulant 150 may include an insulating material. For example, the encapsulant 150 may include a thermosetting resin such as an epoxy resin, a thermoplastic resin such as a polyimide, a prepreg including an inorganic filler and/or a glass fiber, an ABF, FR-4, BT, or a PID.

The package bumps 160 may be disposed in the openings of the second solder mask layer 116 on the lower surface of the substrate 110. The package bumps 160 may physically and/or electrically connect the semiconductor package 100 to an external device such as a main board or the like. The package bumps 160 may have a size and a diameter, greater than those of the plurality of chip bumps 130. The package bumps 160 may include, but are not limited to, a low melting point metal, such as tin (Sn), an alloy including tin (Sn) (Sn—Ag—Cu), or the like. The package bumps 160 may have a land shape, a ball shape, or a pin shape, and may be formed as a single layer or multiple layers. For example, the package bumps 160 may be solder balls.

A signal pattern may correspond to a path (or a part of a path) for exchanging data between the semiconductor package 100 and the external device. The plurality of second pads 112P1 may include at least one second signal pad. Each second signal pad may be electrically connected to at least one first signal pad, among the plurality of first pads 121, to form the signal path. For example, the first and second signal pads may be connected to (or may be parts of) circuit elements that operate when transmitting and/or exchanging data (e.g., data stored to or retrieved from memory cells) or a control signal (e.g., a command signal, a clock signal, or the like).

According to an embodiment, only the plurality of insulating layers 111 may be disposed in an overlapping region OA excluding the plurality of third pads 112P3, among the plurality of interconnection layers, in a region of the substrate 110 overlapping at least one second signal pad forming the signal pattern (path) in the first direction, among the plurality of second pads 112P1.

Among regions of the substrate 110 overlapping the second signal pad in the first direction, only the plurality of insulating layers 111 may be disposed in the overlapping region OA excluding the lowermost interconnection layers 112B. For example, the plurality of insulating layers 111 and the lowermost interconnection layers 112B may be disposed below the second signal pad in the first direction (e.g., along an axis extending parallel to the first direction). For example, in the overlapping region OA, remaining interconnection layers except for the uppermost and lowermost interconnection layers 112T and 112B among the plurality of interconnection layers 112 may not be disposed.

In an overlapping region of a general semiconductor package, remaining interconnection layers except for uppermost and lowermost interconnection layers, among a plurality of interconnection layers, may also be disposed. Therefore, the second signal pad among the plurality of second pads may generate parasitic capacitance with the remaining interconnection layers overlapping in the first direction, and thus the parasitic capacitance may increase. When a signal transmitted by a semiconductor chip is transmitted through a chip bump, parasitic capacitance may change characteristic impedance.

When the characteristic impedance reaches an inflection point due to the parasitic capacitance, quality of the signal may deteriorate. For example, the transmitted signal may be reflected or distorted, and thus the quality of the signal may deteriorate. In addition, the transmitted signal may be lost or an error in timing may occur, and the quality of the signal may deteriorate.

In some embodiments, in the overlapping region OA of an embodiment, the second signal pad among the plurality of second pads 112P1 may not be disposed in the remaining interconnection layers except for the plurality of third pads 112P3. The second signal pad may generate parasitic capacitance only with the plurality of third pads 112P3. Therefore, the parasitic capacitance of the present inventive concept may be smaller than the parasitic capacitance of a general semiconductor package.

Therefore, by reducing the parasitic capacitance, a change in characteristic impedance may be minimized. For example, since the characteristic impedance may be stably maintained, quality of a signal transmitted by the semiconductor chip 120 may be improved when transmitted through the plurality of chip bumps 130.

In some embodiments, a substrate 110 may include a plurality of insulating layers 111 and a plurality of interconnection layers 112, which are alternately stacked in a first direction (Z-direction). A semiconductor chip 120 may include a plurality of chip pads 121, and mounted on the substrate 110 in the first direction. A plurality of chip bumps 130 may be disposed between the plurality of chip pads 121 and the substrate 110.

The plurality of insulating layers 111 may include plural pairs of adjacent two insulating layers, which are partially in contact with each other. Each of the plurality of interconnection layers 112 and at least one of the plurality of insulating layers 111 may be disposed adjacent to and in contact with each other.

The plurality of interconnection layers 112 may include an uppermost interconnection layer 112T, which is closest to the plurality of chip bumps 130 in the first direction among the plurality of interconnection layers 112. The plurality of interconnection layers 112 may include a lowermost interconnection layer 112B, which is farthest from the plurality of chip bumps 130 in the first direction among the plurality of interconnection layers 112. The lowermost interconnection layer 112B may include a plurality of lower pads 112P3. The plurality of lower pads 112P3 may be in contact with one of the plurality of insulating layers 111. The uppermost interconnection layer 112T may include a plurality of upper pads 112P1. The plurality of upper pads 112P1 may be in contact with one of the plurality of insulating layers 111.

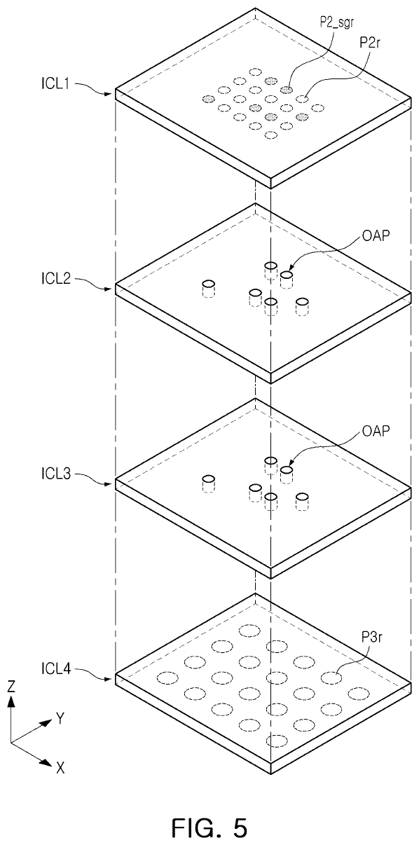

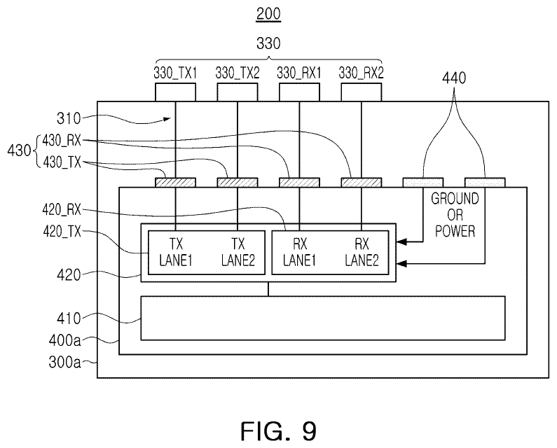

The plurality of chip pads 121 may be electrically connected to the plurality of upper pads 112P1 through the plurality of chip bumps 130, and the plurality of chip pads 121 may include a plurality of chip signal pads (e.g., 430 in FIG. 9). The plurality of upper pads 112P1 may include a plurality of upper signal pads (e.g., pads formed on the upper signal pad regions P2_sgr in FIG. 5), and each chip signal pad (or first signal pad) may be electrically connected to a respective upper signal pad. With respect to a top down view, each chip signal pad and respective upper signal pad may overlap an overlapping region OA of the substrate 110.

Each of the plurality of insulating layers 111 may include an overlapping portion thereof, which overlaps (e.g., entirely overlaps) the overlapping region OA with respect to the top down view. The overlapping portions of any adjacent two insulating layers of the insulating layers may be completely in contact with each other. For example, with respect to a top down view, an area defined by the outermost boundary of the chip signal pad (or first signal pad) may be fully included in the overlapping region OA formed therebelow in the substrate 110. Throughout the overlapping region OA between the second signal pad and the lowermost interconnection layer 112B, each pair of adjacent two insulating layers of the plurality of insulating layers 111 contact each other. For example, the overlapping region OA may be a continuous region that vertically overlaps both the first signal pad and the second signal pad.

The overlapping region OA may extend to a lower surface of a corresponding one (or lower surfaces of ones) of the plurality of upper pads 112P1 (e.g., the upper signal pad). The overlapping region OA may extend to an upper surface of a corresponding one (or upper surfaces of ones) of the plurality of lower pads 112P3. Though FIGS. 1 and 2 show a single overlapping region OA, the invention is not limited thereto, and there may be a plurality of overlapping regions OA in the substrate 110. According to some embodiments, for each of these overlapping regions for signal pads, no voltage or current carrying conductive components (e.g., patterns, lines, etc.), or in some cases, no electrically conductive components, are formed between the level where the upper pads 112P1 are formed and the level where the lower pads 112P3 are formed. For each upper pad 112P1, a corresponding overlapping region OA vertically overlaps an area defined by the outermost boundary of the upper pad 112P1.

FIG. 5 is a view simply illustrating a plurality of interconnection layers to illustrate an overlapping region according to an embodiment.

A semiconductor package may include a substrate, a semiconductor chip, and a plurality of chip bumps. The substrate may include a plurality of insulating layers and a plurality of interconnection layers, and the plurality of insulating layers and the plurality of interconnection layers may be alternately stacked in the first direction (Z-axis of FIG. 5). The substrate may have a plurality of overlapping regions (which may correspond to the overlapping regions OA described above). Among regions of the substrate overlapping a second signal pad in the first direction, a region excluding lowermost interconnection layers may be the overlapping regions. For example, the plurality of overlapping regions may correspond to portions of the plurality of insulating layers. Specific details of the semiconductor package may be similar to or the same as those described above in FIGS. 1 to 4. Throughout the specification, like features and elements have been identified by the same or similar reference numerals and/or letters, and repetitive descriptions may be omitted.

Referring to FIG. 5, a plurality of composite layers ICL1 to ICL4 may be stacked in the first direction. Each of composite layers ICL1 to ICL3 may include a set of conductive vias and one of the plurality of insulating layers. The set of conductive vias may be formed in a corresponding one of the plurality of insulating layers. The plurality of insulating layers of an embodiment illustrated in FIG. 5 may correspond to the plurality of insulating layers 111 of the semiconductor package, described above in FIGS. 1 to 4. For example, at least some of the plurality of interconnection layers (not illustrated) may be disposed between the plurality of composite layers ICL1 to ICL3. The composite layer ICL4 may include a set of pads (which may correspond to the plurality of third pads 112P3 described above) and a solder mask layer (which may correspond to the second solder mask layer described above). The composite layers ICL1, ICL2, ICL3 and ICL4 may be first, second, third and fourth composite layers, respectively.

Among the plurality of interconnection layers, an uppermost interconnection layer may be disposed at an uppermost portion. The uppermost interconnection layer (which corresponds to the uppermost interconnection layers 112T described above) may include a plurality of second pads formed on second pad regions P2r, and at least one of the plurality of second pads may be a second signal pad formed on a second signal pad region P2_sgr, thereby forming a signal pattern (path).

Arrangement of the plurality of second pads may be equal to arrangement of a plurality of chip bumps, with respect to a top down view. The plurality of second pads may be disposed along at least one of the second direction (X-axis of FIG. 5) or the third direction (Y-axis of FIG. 5) on the first composite layer ICL1. The plurality of second pads may be disposed at regular intervals. The arrangement of the plurality of second pads is not limited to the embodiment illustrated in FIG. 5.

Among the plurality of interconnection layers, a lowermost interconnection layer (which may correspond to the lowermost interconnection layers 112B described above) may be disposed in a lowermost portion in the first direction. The lowermost interconnection layer may include a plurality of third pads formed on third pad regions P3r. Arrangement of the plurality of third pads may be equal to the arrangement of the plurality of package bumps with respect to a top down view. The plurality of third pads may be disposed along at least one of the second direction or the third direction of the fourth interconnection layer ICL4. The plurality of third pads may be disposed at regular intervals. The arrangement of the plurality of third pads is not limited to the embodiment illustrated in FIG. 5.

Each of the plurality of overlapping regions may include a corresponding a set of overlapping segments. Each of the second composite layer ICL2 and the third composite layer ICL3 may include at least one overlapping segment OAP in the second composite layer ICL2 and the third composite layer ICL3. Though not shown in the drawing, other overlapping segments may correspond to the portions of the first composite layer ICL1. In each of the plurality of overlapping regions, a corresponding set of overlapping segments may overlap the second signal pad in the first direction (with respect to a top down view).

In each of the sets of overlapping segments, shapes and sizes of the overlapping segments may be the same as or similar to each other. However, the present inventive concept is not limited thereto, and the shape and/or the size may be different from each other.

Referring to FIGS. 1 to 4 together with FIG. 5, each of the plurality of second pads 112P1 may have a cylindrical shape, a side surface of which is inclined such that a diameter of each of the plurality of second pads 112P1 increases in a downward direction (along a direction toward the substrate). The overlapping region OA may be a cylindrical shape having the same upper and lower diameters. For example, a diameter D_OA of each of the overlapping regions OA may be equal to a lower diameter D_112P1 of a corresponding one of the plurality of second pads 112P1.

In another example, the diameter D_OA of each of the overlapping regions OA may be larger than the lower diameter D_112P1 of a corresponding one of the plurality of second pads 112P1.

In each of the overlapping segments, the plurality of interconnection layers 112 may not be disposed, but at least some of the plurality of insulating layers 111 may be disposed. For example, each of the overlapping segments OAP in the second interconnection layer ICL2 and the third interconnection layer ICL3 may be filled with an insulating material instead of a conductive material. Therefore, parasitic capacitance occurring between each of the second signal pads and the second interconnection layer ICL2, and between each of the second signal pads and the third interconnection layer ICL3 may be reduced.

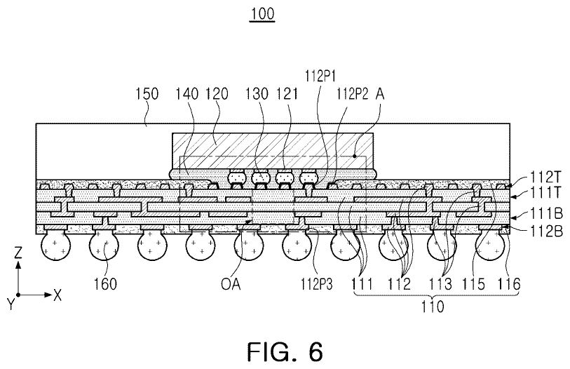

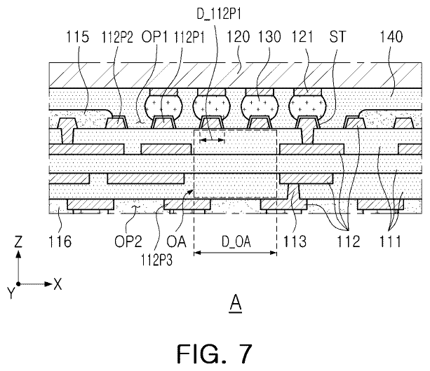

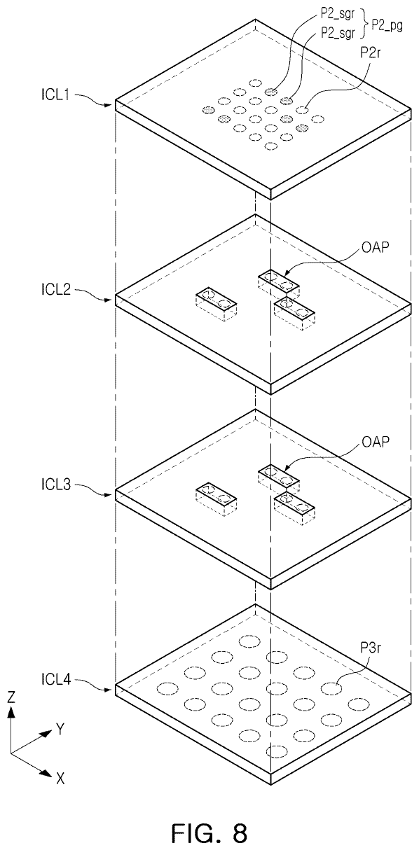

FIG. 6 is a cross-sectional view illustrating a semiconductor package according to an embodiment. FIG. 7 is an enlarged cross-sectional view illustrating region ‘A’ of a semiconductor package according to the embodiment illustrated in FIG. 6. FIG. 8 is a view simply illustrating a plurality of interconnection layers to illustrate an overlapping region according to an embodiment.

Specific details of a semiconductor package 100 illustrated in FIGS. 6 to 8 may be similar to or the same as those described above in FIGS. 1 to 5. A shape and/or a size of an overlapping region OA of the embodiment illustrated in FIGS. 6 to 8 may be different from the embodiment of FIGS. 1 to 5. Hereinafter, a difference in overlapping region OA will be specifically described.

Referring back to FIGS. 1 to 5, the overlapping regions OA of FIGS. 1 to 4 may be defined by each of the second signal pads. Specifically, the overlapping region OA may be a region of the substrate 110 overlapping a corresponding one of the second signal pads in the first direction (Z-axis of FIGS. 1 to 5). In this case, the overlapping region OA may have a cylindrical shape, and a diameter of the overlapping region OA may be equal to or greater than a lower diameter of the second signal pad.

Differently, an overlapping region OA of an embodiment illustrated in FIGS. 6 to 8 may be defined by a plurality of second signal pads formed on second signal pad regions P2_sgr. For example, an overlapping region OA may be defined by a pair of signal pads formed on pair regions P2_pg, each of the signal pads is a part of a signal pattern (path). The pair of signal pads may correspond to a set of the second signal pads.

The pair of signal pads may be disposed adjacently in the second direction (X-axis of FIGS. 6 to 8), parallel to an upper surface of a substrate and perpendicular to the first direction. Arrangement of the pair of signal pads may not be limited thereto. In a region of the substrate 110 overlapping the pair of signal pads in the first direction, only a plurality of insulating layers 111 may be disposed in the overlapping region OA excluding lowermost interconnection layers 112B.

Referring to FIGS. 6 and 7 together with FIG. 8, a second signal pad may have a cylindrical shape, a side surface of which is inclined such that a diameter of the second signal pad increases in a downward direction (along a direction toward the substrate). Referring to FIGS. 6 to 8, the overlapping region OA may have a rectangular parallelepiped shape. Upper surface of the overlapping region OA may be in contact with (or lower than) lower surfaces of the pair of signal pads. For example, with respect to a top down view, an area of the upper and lower surfaces of the overlapping region OA may be larger than a sum of areas of the pair of signal pads. A horizontal length D_OA of the upper and/or lower surfaces of the overlapping region OA may be equal to or greater than a sum of diameters D_112P1 of the second signal pads included in the pair of signal pads in the second direction.

Referring to FIG. 8, overlapping segments OAP included in a second composite layer ICL2 and a third composite layer ICL3 may be filled with an insulating material, respectively, instead of a conductive material. Therefore, parasitic capacitance occurring between the pair of signal pads and each of the second composite layer ICL2 and the third composite layer ICL3 may be reduced.

Comparing the overlapping region OA of FIGS. 1 to 5 with the overlapping region OA of FIGS. 6 to 8, the overlapping region OA of FIGS. 6 to 8 may be larger in size since it may be defined by the pair of signal pads. In the semiconductor package of FIGS. 6 to 8, a reduction range of parasitic capacitance may be larger, such that quality of a signal may be further improved. FIG. 9 is a view illustrating a semiconductor package according to an embodiment.

Referring to FIG. 9, a semiconductor package 200 according to an embodiment may include a substrate 300a and a semiconductor chip 400a. The substrate 300a may be one of the substrates 110, which are illustrated with reference to FIGS. 1 to 8.

The substrate 300a may provide a layout space (e.g., areas or regions) for a plurality of external terminals 330, the semiconductor chip 400a, and a plurality of lanes 310. The substrate 300a may have a structure in which at least one interconnection layer and at least one insulating layer are alternately stacked. For example, the interconnection layer of the substrate 300a may include an interconnection line or a redistribution line, and the plurality of lanes 310 may be implemented as at least one of an interconnection line, a redistribution line, or a conductive via. The plurality of lanes 310 may be included in the interconnection layer. For example, the substrate 300a may include a plurality of insulating layers, a plurality of interconnection layers and at least one overlapping region, which are the same as or similar to those illustrated with reference to FIGS. 1 to 8. The plurality of interconnection layers include interconnection patterns. The interconnection patterns may be at least part of interconnection lines or redistribution lines.

The plurality of external terminals 330 may provide electrical connection paths for an additional semiconductor chip or an additional substrate. For example, the plurality of external terminals 330 may be at least one of a bump, a solder ball, a bonding wire, or a post, and may electrically connect and secure connection between an additional semiconductor chip and/or an additional substrate, provided externally, and the substrate 300a. For example, the plurality of external terminals 330 may correspond to the plurality of package bumps 160, which are illustrated with reference to FIGS. 1 to 8.

The semiconductor chip 400a may be electrically connected to the plurality of external terminals 330 through a plurality of pads 430 and the plurality of lanes 310. A plurality of external transmission terminals 330_TX1 and 330_TX2 and a plurality of external reception terminals 330_RX1 and 330_RX2 may be included. The semiconductor chip 400a may transmit transmission signals toward the plurality of external transmission terminals 330_TX1 and 330_TX2, and may receive reception signals from the plurality of external reception terminals 330_RX1 and 330_RX2.

The semiconductor chip 400a may include a controller 410 and an interface circuit 420. The controller 410 may receive a signal from a processor, a computing system, or the like of an external electronic device, and may generate control information, based on the signal. The interface circuit 420 may generate a plurality of transmission signals containing the control information, or generate reception information from a plurality of reception signals. For example, the controller 410 may control a plurality of memory chips (or memory cells) by generating the control information and using the reception information according to a universal flash storage (UFS) specification.

For example, the interface circuit 420 may correspond to a physical layer and/or a protocol layer of a network communication layer. The controller 410 may correspond to at least a portion and/or an application of the protocol layer of the network communication layer. For example, when the semiconductor chip 400a generates a transmission signal and converts a reception signal according to M-PHY of a mobile industry processor interface (MIPI), the M-PHY may correspond to the physical layer, and the protocol layer may correspond to CSI-3 of the MIPI.

For example, the semiconductor chip 400a may include the interface circuit 420 generating the transmission signal or converting the reception signal according to a specific interface method. In this case, the specific interface method may be the M-PHY of the mobile industry processor interface (MIPI). The interface circuit 420 may include a transmission interface circuit 420_TX generating transmission signals, and a reception interface circuit 420_RX converting reception signals. The transmission interface circuit 420_TX may transmit first transmission signals through a first transmission terminals TX LANE1, and may transmit second transmission signals through a second transmission terminals TX LANE2. The reception interface circuit 420_RX may receive first reception signals through first reception terminals RX LANE1, and may receive second reception signals through second reception terminals RX LANE2.

A data transmission speed of transmission signals passing through a plurality of transmission lanes of the plurality of lanes 310 and a data transmission speed of reception signals passing through a plurality of reception lanes of the plurality of lanes 310 may exceed 3 Gbps. For example, a data transmission speed of signals according to D-PHY and C-PHY of MIPI may be less than 3 Gbps, but a data transmission speed of transmission signals and a data transmission speed of reception signals according to M-PHY of MIPI may exceed 3 Gbps, and may be faster, depending on a control method of the controller 410. For example, a data transmission speed according to a UFS4.0 control method may be faster than 24 Gbps.

As the data transmission speed of the transmission signals and the data transmission speed of the reception signals increase, a fundamental frequency of the transmission signals and a fundamental frequency of the reception signals may increase. As the fundamental frequency of the transmission signals and the fundamental frequency of the reception signals increase, it may be important for characteristic impedance of the plurality of lanes 310 to be maintained in a predetermined range, lower than an inflection point.

The plurality of pads 430 included in the semiconductor chip 400a may include a plurality of transmission pads 430_TX and a plurality of reception pads 430_RX. The plurality of lanes 310 may include a plurality of transmission lanes and a plurality of reception lanes, the plurality of transmission lanes may be electrically connected between the plurality of transmission pads 430_TX and the plurality of external transmission terminals 330_TX1 and 330_TX2, and the plurality of reception lanes may be electrically connected between the plurality of reception pads 430_RX and the plurality of external reception terminals 330_RX1 and 330_RX2. For example, the plurality of pads 430 may correspond to the chip signal pads, which are illustrated with reference to FIGS. 1 to 8.

Input of at least one ground/power pad 440 may correspond to ground GROUND or power POWER. For example, the ground/power pad 440 may be one of the plurality of pads 430, which are illustrated with reference to FIGS. 1 to 8, and may be other than the chip signal pad.

The signal pattern (path) of the semiconductor package may be composed of the plurality of pads 430, the plurality of lanes 310, and the plurality of external terminals 330. Referring to FIGS. 1 to 8, the first to third pads, the chip bumps, the plurality of interconnection layers, and the package bumps, forming the signal pattern, may be included in the plurality of pads 430, the plurality of lanes 310, and the plurality of external terminals 330. For example, the signal path may include the first to third pads, the chip bumps, the plurality of interconnection layers, and/or the package bumps, which are illustrated with reference to FIGS. 1 to 8.

In a semiconductor package 200 of an embodiment, parasitic capacitance of the signal pattern may be minimized. Therefore, characteristic impedance of the signal pattern may be maintained in a predetermined range, lower than an inflection point.

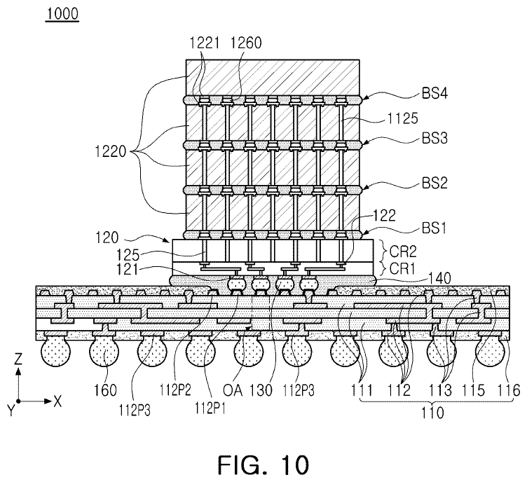

FIG. 10 is a cross-sectional view illustrating a semiconductor package according to an embodiment.

Referring to FIG. 10, a semiconductor package 1000 may further include a plurality of upper semiconductor chips 1220 stacked and disposed in the first direction (Z-axis of FIG. 10) on a semiconductor chip 120, unlike the embodiment of FIG. 2. The semiconductor package 1000 may be a SIP (System in Package), in which the semiconductor chip 120 may be a logic semiconductor chip, and the upper semiconductor chips 1220 may be memory semiconductor chips. Specific details of a substrate 110, a semiconductor chip 120, a plurality of chip bumps 130, and a plurality of package bumps 160 may be the same or similar to the embodiments of the semiconductor package 100 described above with reference to FIGS. 1 to 8.

The semiconductor chip 120 of the present embodiment may have a first region CR1 in a lower portion and a second region CR2 in an upper portion, and may further include element layers 122 and through-vias 125. The first region CR1 may be an element region, and may be a region in which elements such as transistors and/or memory cells forming the semiconductor chip are formed, based on the second region CR2. The second region CR2 may be a substrate region, and may be a region including a semiconductor material such as silicon (Si), for example.

The element layers 122 may be disposed in the first region CR1 to form the devices. The through-vias 125 may penetrate the second region CR2 of the semiconductor chip 120. In some embodiments, the through-vias 125 may further penetrate at least a portion of the first region CR1. The through-vias 125 may be electrically connected to the element layers 122 of the first region CR1, and may provide an electrical connection between the upper semiconductor chips 1220 and the substrate 110. The through-vias 125 may be formed of a conductive material, and may include, for example, at least one of tungsten (W), aluminum (Al), or copper (Cu).

The upper semiconductor chips 1220 may be stacked in the first direction (Z-axis in FIG. 10) on the semiconductor chip 120. The upper semiconductor chips 1220 may include through-vias 1125 except for the upper semiconductor chip 1220 in an uppermost portion. A first connection region BS1 may be formed between the semiconductor chip 120 and the upper semiconductor chip 1220, and second to fourth connection regions BS2, BS3, and BS4 may be located between corresponding two chips of the upper semiconductor chips 1220, respectively. The first to fourth connection regions BS1, BS2, BS3, and BS4 may have a structure substantially the same as or similar to a connection region between the substrate 110 and the semiconductor chip 120.

For example, in each of the first to fourth connection regions BS1, BS2, BS3, and BS4, a plurality of first bumps 1260 may be connected between a plurality of upper chip pads 1221 of corresponding two chips of the upper semiconductor chips 1220 and the semiconductor chip 120. The plurality of first bumps 1260 may be implemented similarly to the plurality of chip bumps 130, and may thus have a melting point, lower than a melting point of the plurality of upper chip pads 1221, but are not limited thereto.

In an overlapping region OA of an embodiment, among a plurality of second pads 112P1, a second signal pad may not be disposed in remaining interconnection layers except for a plurality of third pads 112P3. The second signal pad may generate parasitic capacitance only with the plurality of third pads 112P3. Therefore, the parasitic capacitance of the present inventive concept may be minimized.

Specific details of the overlapping region OA may be similar to or the same as those described above in FIGS. 4 to 8. Alternatively, specific details of the overlapping region OA may be applied by merging the shapes and/or sizes described above in FIGS. 4 to 8. For example, the shapes and/or sizes described above in FIGS. 4 to 8 may be modified and/or combined, as long as they remain within the spirit and scope of the invention.

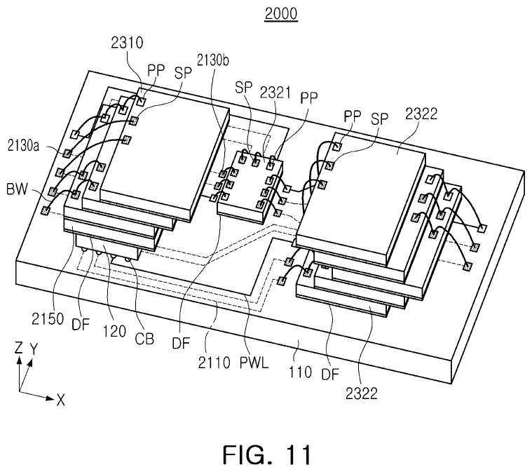

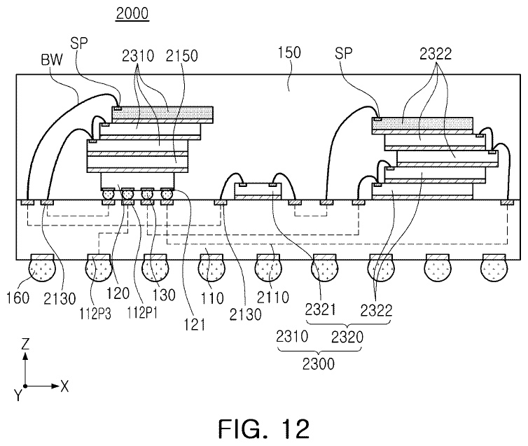

FIG. 11 is a perspective view illustrating a semiconductor package according to an embodiment. FIG. 12 is a side view illustrating a semiconductor package according to the embodiment illustrated in FIG. 11.

A semiconductor package 2000 of an embodiment illustrated in FIGS. 11 and 12 may further include a plurality of memory chips 2310 and 2320 and a plurality of conductive wires BW. Specific details of a substrate 110, a semiconductor chip 120, a plurality of chip bumps 130, an encapsulant 150, and a plurality of package bumps 160 may be the same as or similar to the embodiments of the semiconductor package 100 described above with reference to FIGS. 1 to 8.

Referring to FIGS. 11 and 12, a plurality of external terminals 2130 may be disposed on an upper surface and/or a lower surface of the substrate 110, and may be electrically connected to at least one of the plurality of memory chips 2310 and 2320. The plurality of external terminals 2130 of FIGS. 11 and 12 may be electrically connected to a plurality of pads SP disposed on upper surfaces of the plurality of memory chips 2310 and 2320 through the plurality of bonding wires BW. The plurality of memory chips 2310 and 2320 may be electrically connected to the substrate 110 through the plurality of bonding wires BW without a plurality of chip bumps.

One end of the plurality of bonding wires BW may be electrically connected to signal pads SP or power pads PP. The other end of the plurality of bonding wires BW may be connected to the plurality of external terminals 2130 of the substrate 110. Each of the conductive wires BW may contain a metal material having high conductivity, such as gold (Au), aluminum (Al), or copper (Cu).

For example, the plurality of external terminals 2130 and the plurality of memory chips 2310 and 2320 may be electrically connected to each other through at least one of a bump, a solder ball, or a post. For example, the plurality of external terminals 2130 may be electrically connected to an additional semiconductor chip or an additional substrate through the plurality of package bumps 160.

The semiconductor chip 120 may be mounted on the upper surface of the substrate 110 through the plurality of chip bumps 130. For example, the plurality of chip bumps 130 may be connected and fixed to the semiconductor chip 120 and the substrate 110 through a thermal compression bonding (TCB) process or a reflow process. In this case, a plurality of first pads 121 disposed on a lower surface of the semiconductor chip 120 may be electrically connected to a plurality of lanes 2110.

The plurality of memory chips 2310 and 2320 may include at least one of first memory chips 2310, a buffer memory chip 2321, or second memory chips 2322, and may be a memory device in the form of a high bandwidth memory (HBM) having an increased bandwidth by including a plurality of channels having independent interfaces. The first memory chips 2310 may be electrically connected to the semiconductor chip 120 without the buffer memory chip 2321, and the second memory chips 2322 may be electrically connected to the semiconductor chip 120 through the buffer memory chip 2321. The buffer memory chip 2321 may buffer command information and address information transmitted to and/or received from the second memory chips 2322, and may store a queue. The first and second memory chips 2310 and 2322 may perform a write operation or a read operation, according to the command information and the address information. For example, each of the plurality of memory chips 2310 and 2320 may be implemented as a volatile memory (e.g., a static random access memory (SRAM), a dynamic RAM (DRAM), a synchronous RAM (SDRAM), or the like) or a non-volatile memory (e.g., a flash memory, a phase-change RAM (PRAM), a magneto-resistive RAM (MRAM), a resistive RAM (ReRAM), a ferro-electric RAM (FRAM), or the like).

Each of the plurality of memory chips 2310 and 2320 and the semiconductor chip 120 may include a body portion containing a semiconductor material such as silicon (Si), germanium (Ge), or gallium arsenide (GaAs), and an element layer disposed below the body portion and including an integrated circuit (IC). A plurality of first pads 121 disposed on a lower surface of the semiconductor chip 120 may be disposed below the element layer. The plurality of first pads 121 may be electrically connected to the element layer through a back-end-of-line (BEOL). The plurality of first pads 121 may include a conductive material such as tungsten (W), aluminum (Al), copper (Cu), or the like.

The plurality of memory chips 2310 and 2320 may be bonded to each other or to the substrate 110 through adhesive layers (DF). A spacer member 2150 may be disposed between some of the plurality of memory chips 2310 and 2320 and the semiconductor chip 120, and the semiconductor chip may have a structure in which there is no semiconductor circuit. Depending on a design, some of the plurality of memory chips 2310 and 2320 and the semiconductor chip 120 may be vertically electrically connected to each other through through-vias formed vertically in each of the plurality of memory chips 2310 and 2320 and the semiconductor chip 120.

The encapsulant 150 such as an epoxy molding compound (EMC) may be filled in a space on the upper surface of the substrate 110 that may not be occupied by the plurality of memory chips 2310 and 2320 and the semiconductor chip 120, thereby sealing the plurality of memory chips 2310 and 2320 and the semiconductor chip 120. A power line PWL may be electrically connected to power pads PP disposed on upper surfaces of the plurality of memory chips 2310 and 2320, and may provide power. For example, the power may be provided from the outside through some of the plurality of external terminals 2130, and may also be provided to the semiconductor chip 120.

The semiconductor chip 120 may be a host for the plurality of memory chips 2310 and 2320, and may transmit transmission signals to the plurality of memory chips 2310 and 2320 or receive reception signals from the plurality of memory chips 2310 and 2320 through a host interface. The host interface may be, but is not limited to, a universal flash storage (UFS). For example, the host interface may be at least one of a peripheral component interconnect express (PCIe), a non-volatile memory express (NVMe), a serial attached SCSI (SAS), a small computer system interface (SCSI), an SCSIe, a serial advanced technology attachment (SATA), SATAe, a computer express link (CXL), or a Gen-Z.

According to a design, the plurality of memory chips 2310 and 2320 may be replaced with a plurality of non-memory chips, and the semiconductor chip 120 may transmit the transmission signals to the plurality of non-memory chips or receive the reception signals from the plurality of non-memory chips through a chiplet interface such as a universal chip interconnect express (UCIe).

According to an embodiment, a conductive material may not be interposed between the second signal pad and the third pads 112P3 among the plurality of second pads 112P1. Since parasitic capacitance between the second signal pad and the third pad 112P3 overlapping the second signal pad in the first direction (Z-axis direction of FIGS. 11 and 12) may be minimized, characteristic impedance of the signal pattern (path) may be controlled to a predetermined range below an inflection point. For example, according to some aspects of the invention, the characteristic impedance of the signal path may be within a predetermined range that is below a critical or threshold point, where the impedance might cause undesired effects.

In a semiconductor package according to an embodiment, only an insulating layer may be disposed between an upper pad of a substrate connected to a semiconductor chip and forming a signal pattern, and a lower pad of the substrate connected to a package bump, thereby reduce parasitic capacitance between the pads to minimize a change in characteristic impedance. Therefore, quality of a signal transmitted to the substrate may be improved.

Advantages and effects of the present inventive concept are not limited to the above-described contents, and other advantages and effects will be more easily understood in the process of explaining the specific embodiments described above.

While example embodiments have been illustrated and described above, it will be apparent to those skilled in the art that modifications and variations could be made without departing from the scope of the present inventive concept as defined by the appended claims.

What is claimed is:

1. A semiconductor package comprising:
a substrate including a plurality of insulating layers and a plurality of interconnection layers stacked in a first direction;
a semiconductor chip including a plurality of first pads, and mounted on the substrate; and
a plurality of chip bumps disposed between the plurality of first pads and the substrate,
wherein:
the plurality of interconnection layers include an uppermost interconnection layer and a lowermost interconnection layer,
each interconnection layer of the plurality of interconnection layers is disposed in a corresponding insulating layer among the plurality of interconnection layers,
the uppermost interconnection layer includes a plurality of second pads that are electrically connected to the plurality of first pads through the plurality of chip bumps,
the plurality of second pads are in contact with one of the plurality of insulating layers,
the plurality of first pads include a first signal pad, and the plurality of second pads include a second signal pad that is electrically connected to the first signal pad,
with respect to a top down view, an area defined by an outermost boundary of the first signal pad is fully included in an overlapping region disposed therebelow in the substrate, and
throughout the overlapping region between the second signal pad and the lowermost interconnection layer, each pair of two adjacent insulating layers among the plurality of insulating layers contact each other.

2. The semiconductor package of claim 1, wherein the plurality of insulating layers are disposed between the uppermost interconnection layer and the lowermost interconnection layer in the first direction.

3. The semiconductor package of claim 1, wherein:
each of the plurality of second pads has a cylindrical shape,
a side surface of each of the plurality of second pads is inclined, and
a diameter of each of the plurality of second pads increases along a direction toward the substrate.

4. The semiconductor package of claim 3, wherein the overlapping region has a cylindrical shape, and diameters of upper and lower portions of the overlapping region are the same as each other.

5. The semiconductor package of claim 4, wherein a diameter of the overlapping region is equal to a diameter of a lower portion of the second signal pad.

6. The semiconductor package of claim 4, wherein a diameter of the overlapping region is greater than a diameter of a lower portion of the second signal pad.

7. The semiconductor package of claim 1, further comprising a first solder mask layer on the substrate.

8. The semiconductor package of claim 7, wherein the first solder mask layer is spaced apart from at least some of the plurality of second pads.

9. The semiconductor package of claim 8, wherein the overlapping region is spaced apart from the first solder mask layer.

10. The semiconductor package of claim 9, wherein each of the plurality of second pads is spaced apart entirely from the first solder mask layer.

11. A semiconductor package comprising:
a substrate including a plurality of insulating layers and a plurality of interconnection layers;
a semiconductor chip mounted on the substrate; and
a plurality of chip bumps disposed between the substrate and the semiconductor chip,
wherein:
the plurality of interconnection layers include an uppermost interconnection layer disposed at an uppermost portion of the substrate and a lowermost interconnection layer disposed in a lowermost portion of the substrate,
the uppermost interconnection layer includes a first signal pad,
with respect to a top down view, an area defined by an outermost boundary of the first signal pad is fully included in a first region formed therebelow in the substrate, and
within the first region in the substrate, no electrically conductive layers are disposed between the first signal pad and the lowermost interconnection layer.

12. The semiconductor package of claim 11, wherein the plurality of insulating layers are disposed between the uppermost interconnection layer and the lowermost interconnection layer.

13. The semiconductor package of claim 11, wherein
the uppermost interconnection layer further includes a second signal pad that forms a pair of signal pads with the first signal pad, and
each signal pad of the pair of signal pads has a cylindrical shape, a side surface of which is inclined such that a diameter of each signal pad of the pair of signal pads increases along a direction toward the substrate.

14. The semiconductor package of claim 13, wherein:
the first region has a rectangular parallelepiped shape, and
the first region extends to lower surfaces of the pair of signal pads.

15. The semiconductor package of claim 14, wherein horizontal lengths of an upper surface or a lower surface of the first region are equal to or greater than a sum of horizontal diameters of each of the pair of signal pads.

16. A semiconductor package comprising:
a substrate including a plurality of insulating layers and a plurality of interconnection layers;
a semiconductor chip including a plurality of first pads and mounted on the substrate in a first direction;
a plurality of chip bumps disposed on an upper surface of the substrate; and
a plurality of package bumps disposed on a lower surface of the substrate,
wherein:
the plurality of interconnection layers include a plurality of second pads connected to the plurality of first pads and the plurality of chip bumps, and a plurality of third pads connected to the plurality of package bumps, and
only the plurality of insulating layers are disposed in an overlapping region of the substrate excluding the plurality of third pads, in a region of the substrate overlapping at least one second signal pad in the first direction, among the plurality of second pads.

17. The semiconductor package of claim 16, further comprising:
a first solder mask layer forming the upper surface of the substrate; and
a second solder mask layer forming the lower surface of the substrate.

18. The semiconductor package of claim 17, wherein the first solder mask layer includes a first opening exposing the plurality of second pads.

19. The semiconductor package of claim 17, wherein the second solder mask layer includes a plurality of second openings exposing the plurality of third pads.

20. The semiconductor package of claim 17, wherein:
the overlapping region is included in a region of the substrate overlapping the second signal pad in the first direction,
the overlapping region is spaced apart from the first solder mask layer, and
the overlapping region is connected to the second solder mask layer.
